(19) United States
(12) Patent Application Publication
(10) Pub. No.: US 2012/0307461 A1
(43) Pub. Date: Dec. 6, 2012

(54) Flexible Circuit Board and Electric Device

(75) Inventor: Uwe Liskow, Asperg (DE)

(73) Assignee: Robert Bosch GmbH, Stuttgart (DE)

(21) Appl. No.: 13/511,798

(22) PCT Filed: Oct. 7, 2010
(86) PCT No.: PCT/EP2010/064990

§ 371 Date: Aug. 14, 2012

(30) Foreign Application Priority Data
Dec. 1, 2009 (DE) 10 2009 047 329.7

(51) Int. Cl. H05K 1/02; H05K 1/14

(52) U.S. Cl. 361/749; 174/251

(57) ABSTRACT

A flexible circuit board is provided. The flexible circuit board includes a conductive path and a shell that at least regionally surrounds the conductive path. The shell is fastened to the conductive path with an adhesive layer between the conductive path and the shell. The shell is enveloped at least regionally by a cover. A filler layer is provided between the shell and the cover. The flexible circuit board is used in an electric device.

The invention relates to a flexible circuit board comprising at least one conductor track and at least one sheath at least locally enclosing the conductor track, at least one adhesive layer for fastening the sheath being provided between the conductor track and the sheath. The invention furthermore relates to an electrical device.

### PRIOR ART

Flexible circuit boards and electrical devices of the type mentioned in the introduction are known from the prior art. For example, DE 10 2004 061 818 A1 discloses a control module which may be used in particular for a motor vehicle transmission. A flexible circuit board, which is referred to in said document as a flexible printed circuit foil, is provided there for electrically connecting a circuit component arranged in an interior of a housing of a control unit to electrical components arranged outside the housing interior. The flexible circuit board comprises the at least one conductor track, which is at least locally enclosed by the sheath. The adhesive layer is provided between the conductor track and the sheath, in order to fasten the conductor track in relation to the sheath. With a flexible circuit board of this type, however, the problem arises that the conductor track obtrudes on the sheath, that is to say the sheath is curved outward in the region of the conductor track. If a flexible circuit board of this type is intended to be led out from an electrical device, for example the control unit for a vehicle, then sealing in this region is only insufficiently possible or extremely difficult. Good, in particular hermetic, sealing of the electrical device is however necessary for some fields of use. This applies, for example, when the device is exposed to hot, cold and/or aggressive transmission oil or the like. Ingress of this transmission oil into the electrical device is undesirable, so as to avoid damage or impairment of the functionality. Although it is already known to introduce connection regions of the device, in particular of a transmission control unit (TCU), into a steel housing, and thereby seal the device, such a procedure is often unusable, above all owing to the large installation space required, high costs and/or the need to lead the flexible circuit board out from the device without using further intermediate parts and/or intermediate connections (such as the connection region).

### DISCLOSURE OF THE INVENTION

In relation to the flexible circuit boards known from the prior art, the flexible circuit board having the features of claim 1 has the advantage that it comprises a surface which makes it possible to lead it out from the electrical device while nevertheless sealing the latter without great outlay. This is achieved according to the invention by providing a cover which at least locally lies over the sheath, at least one filler layer being provided between the sheath and the cover. As already described above, in the case of the flexible circuit boards known from the prior art the at least one conductor track obtrudes on the sheath, so that the flexible circuit board has a relief-like profile in cross section. For this reason, the additional cover is provided which at least locally lies over the sheath. The filler layer is arranged between the sheath and the cover. The filler layer ensures that the relief-like profile of the sheath is compensated for so that the cover, which lies over the filler layer, is at least almost flat. The sheath and the cover may consist of different materials. For example, the sheath will consist of polyimide (PI) and the cover will consist of a thermoplastic or rubber-elastic material. Preferably, the cover only locally surrounds the sheath, so as not to compromise the flexibility of the circuit board. In order to achieve this, the cover is provided for example only in the region of an opening of the electrical device, through which the circuit board is led out from the electrical device, or a housing thereof.

According to one refinement of the invention, the filler layer establishes an adhesive bond between the sheath and the cover. To this end, the filler layer may likewise be an adhesive layer or at least comprise adhesive. In this way, by means of the filler layer, the unevennesses of the sheath can be compensated for and at the same time the cover is fastened on the sheath. This allows economical production of the flexible circuit board.

According to one refinement of the invention, at least one compensation element comprising a plastic and/or a metal or consisting of plastic and/or metal is arranged in the filler layer. In order to achieve the plane surface of the cover, the compensation element may be arranged in the filler layer. For example, a plurality of strip-shaped compensation elements may be arranged so that—as seen in cross section—they each lie next to the conductor track. They are thus positioned so they at least compensate for the elevations which are caused by the conductor track in the sheath. Remaining unevennesses are eliminated by means of the filler layer, so that the conductor track cannot obtrude also on the cover and a plane surface of the flexible circuit board is achieved in the region of the cover. Preferably, the material of which the compensation element consists is durable and has similar thermal expansion properties to the cover. In this way, the flexible circuit board is not damaged by heating or cooling which would entail differential expansion of the individual components of the circuit board. The compensation element consists for example of plastic or metal, or at least comprises these materials. If metal is provided at least locally, then the compensation element can simultaneously be used as electrical shielding against interference. To this end, the compensation element is preferably connected to an electrical ground potential. Shaping or preforming of the flexible circuit board can also be carried out by means of the compensation element. This is achieved in particular by the use of metal. Likewise, however, a plastic, in particular a thermoplastic, may be used in order to achieve the preforming of the circuit board. After its production, for example, the flexible circuit board may in this way be heated, shaped and subsequently recooled.

According to one refinement of the invention, a sealing element, in particular a lip seal, is provided on the cover. The sealing element may be applied on the cover or formed integrally therewith. The latter may be advantageous in particular when the cover consists of a thermoplastic or rubber-elastic material. The sealing element is in this case formed so that an opening, in which the flexible circuit board is arranged, is sealed. To this end, the sealing element may be formed as a lip seal. The latter is preformed so that it comes in touching contact with side walls of the opening when the circuit board is arranged in the opening of the electrical device, and thereby seals the opening. In order to achieve particularly good sealing, a plurality of sealing elements or lip seals may also be provided.

According to one refinement of the invention, the cover is formed by a circumferential sleeve and/or a one-piece or multi-piece cover element. The cover may be applied onto the sheath in various ways. For example, the cover may be configured as a circumferential sleeve which is to be slid over the sheath, with the conductor track contained therein, during production of the flexible circuit board. In this case, for example, the sheath is arranged in a U-shape and inserted into the sleeve. After the filler layer has been introduced, the sheath together with the sleeve, or the cover, is brought into the desired, e.g. plane, shape. The sleeve constitutes one embodiment of the one-piece cover element. It is furthermore possible to use a one-piece cover element not formed as a sleeve. This is placed around the sheath, or the filler layer, and the two ends are connected together in the region of a connection position, so that the cover is essentially closed. As an alternative, it is also possible to use a multi-piece cover element, in which case for example two sheets, which together form the cover element, are placed around the sheath, or the filler layer. The sheets are subsequently connected together so that the cover has the desired plane configuration.

According to one refinement of the invention, the one-piece or multi-piece cover element comprises at least one connection position where a first region of the cover element abuts or forms a seam or an overlap with a second region of the cover element. In the connection position, the first region and the second region of the cover element are connected together or at least arranged so that the filler layer is protected against external influences, and at the same time the cover has a plane surface. For example, the regions may abut, i.e. be arranged in a planar fashion with respect to one another. It is, however, likewise possible to provide the two regions with a seam or an overlap.

The invention furthermore relates to an electrical device, in particular a control unit for a vehicle, comprising at least one flexible circuit board, in particular according to the embodiments above, the circuit board comprising at least one conductor track and at least one sheath at least locally enclosing the conductor track, and at least one adhesive layer for fastening the sheath being provided between the conductor track and the sheath, and the conductor track being led out from a housing of the device through an opening. In this case, a cover which at least locally lies over the sheath is provided, at least one filler layer being provided between the sheath and the cover. Owing to the cover and the filler layer, an essentially plane surface of the flexible conductor track is achieved. It can therefore be led out from the housing of the device, preferably configured in a plurality of pieces, without compromising the leaktightness of the housing. The housing consists for example of two curved plates, which are connected together during production of the electrical device. The electrical conductor track is in this case usually arranged between the two curved plates and, for example, held clamped. In order to obtain sufficient space for the arrangement of the conductor track, at least one of the curved plates comprises the opening. In the region of the opening, the housing may also comprise sealing means which come in touching contact with the flexible circuit board after assembly of the housing, or of the electrical device, and thus ensure additional sealing of the housing. In addition, as already mentioned above, the cover may comprise a sealing element and, in particular, a lip seal. The sealing element is in this case arranged for further sealing of the housing.

According to one refinement of the invention, the housing is at least locally filled with a filler compound. The filler compound is for example a potting compound, with which the housing of the device is at least partially filled in order to protect components arranged in the housing better against external influences. The filler compound may be a thermosetting plastic, thermoplastic or other plastic.

According to one refinement of the invention, the cover is provided at least in the region of the opening. The flexibility of the flexible circuit board is preserved in this way, since it is additionally rigidified by the cover only in the region of the opening. The cover is in this case used merely to ensure the leaktightness of the housing, by virtue of the fact that it provides a plane surface of the flexible circuit board.

According to one refinement of the invention, the cover consists of a material, in particular plastic and/or metal, which enters into a bond with the filler compound. The flexible circuit board, or the cover, is at least locally introduced into the housing of the electrical device. In order to fasten the flexible circuit board securely with respect to the housing, the cover is bonded to the filler compound so that the flexible circuit board is held on or in the housing by a material-fit connection.

The invention will be explained in more detail below with the aid of the exemplary embodiments represented in the drawing, without limiting the invention.

FIG. 1 shows a flexible circuit board known from the prior art,

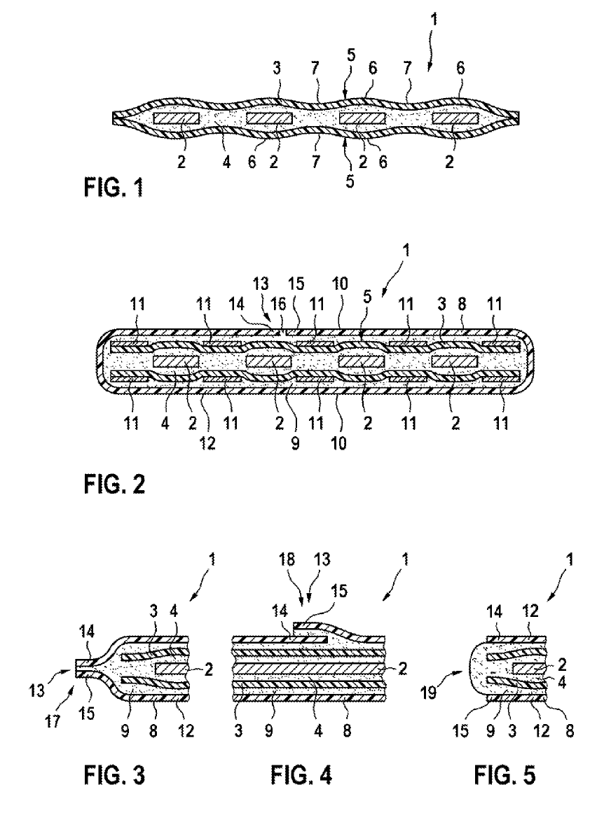

FIG. 2 shows a flexible circuit board comprising a cover and a filler layer in a first embodiment,

FIG. 3 shows a region of the flexible circuit board in a second embodiment,

FIG. 4 shows a region of the flexible circuit board in a third embodiment,

FIG. 5 shows a region of the flexible circuit board in a fourth embodiment,

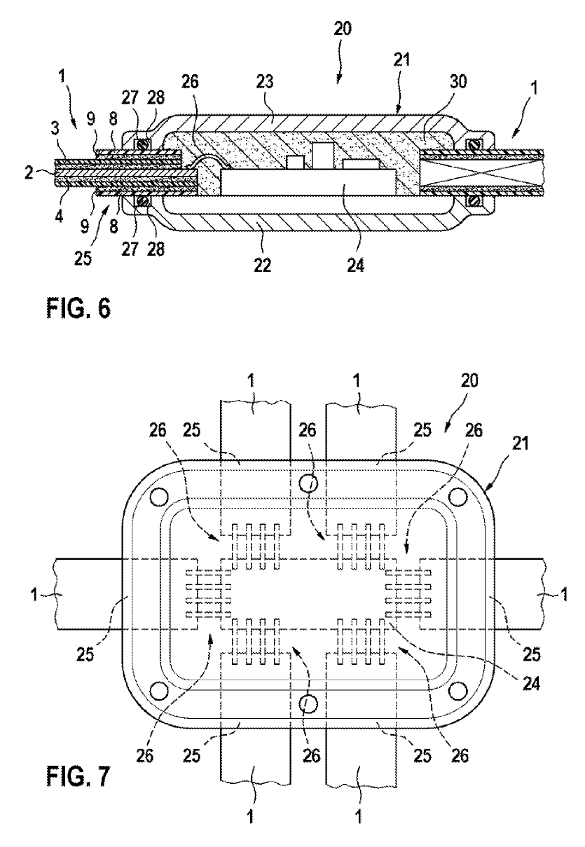

FIG. 6 shows an electrical device comprising a flexible circuit board, in a sectional view,

FIG. 7 shows the device in a view from above,

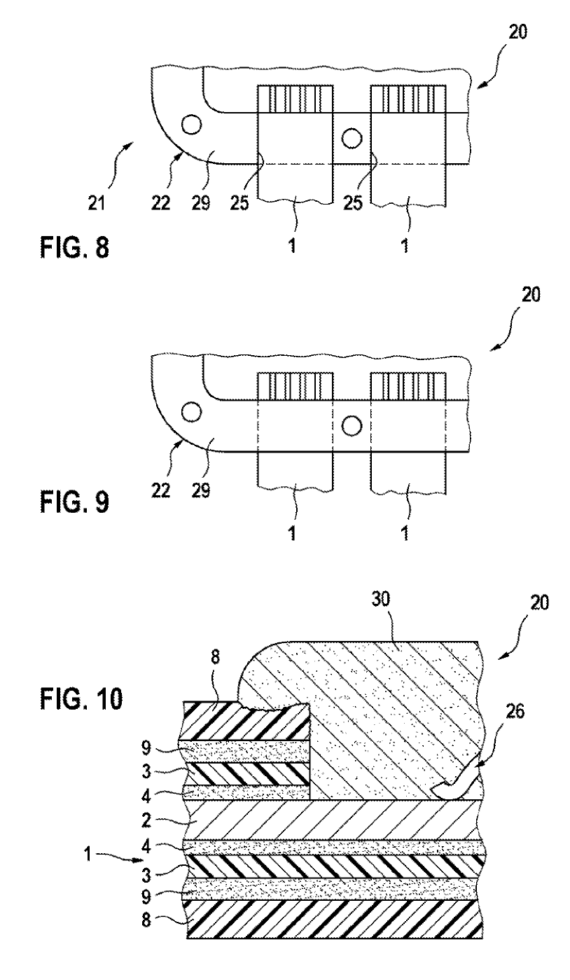

FIG. 8 shows a region of the electrical device comprising two flexible circuit boards in a first production step,

FIG. 9 shows the arrangement known from FIG. 8 in a second production step,

FIG. 10 shows a detail view of the electrical device known from FIG. 6 in the region of the flexible circuit board, and

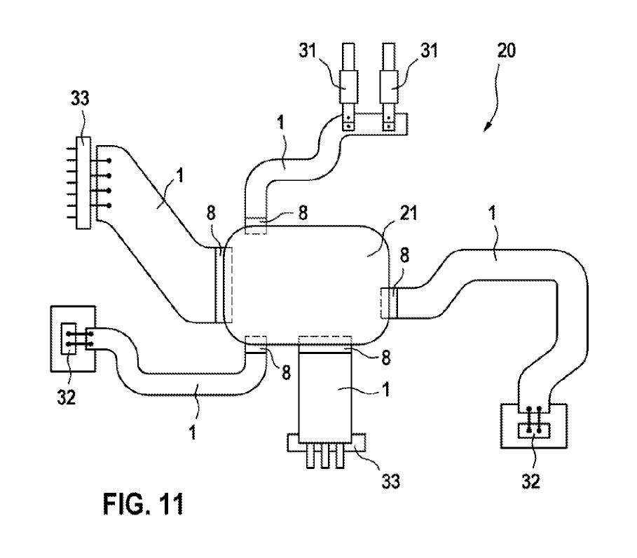

FIG. 11 shows a further embodiment of the electrical device.

FIG. 1 shows a flexible circuit board 1 known from the prior art, which consists of a plurality of conductor tracks 2 enclosed by a sheath 3, which is fastened by means of an adhesive layer 4. The adhesive layer 4 thus surrounds the conductor tracks 2, and the sheath 3 surrounds both the adhesive layer 4 and the conductor tracks 2. It can be seen clearly that the conductor tracks 2 obtrude significantly on surfaces 5 of the flexible circuit board 1. Elevations 6 are formed in the region of the conductor tracks 2, and depressions 7 are formed between the elevations 6. As seen in cross section, there is thus a relief-like profile of the surfaces 5 of the flexible circuit board 1.

FIG. 2 shows an embodiment according to the invention of the flexible circuit board 1. Like the embodiment represented in FIG. 1, the circuit board 1 shown here comprises conductor tracks 2 which are surrounded by an adhesive layer 4 and a sheath 3. On the surface 5 of the sheath 3, or of the circuit board 1, there is thus again the relief-like profile. For this reason, provision is additionally made for the sheath 3 to be overlaid at least locally with a cover 8. A filler layer 9 is in this case provided between the sheath 3 and the cover 8. The filler layer 9 establishes an adhesive bond between the sheath 3 and the cover 8, and thus holds the cover 8 on the sheath 3. The effect intended to be achieved by the filler layer 9 is that surfaces 10 of the cover 8, or of the flexible circuit board 1, are essentially planar, i.e. they no longer have the relief-like profile of the surface 5 of the sheath 3. In addition to the filler layer 9, compensation elements 11 may be arranged in order to achieve this purpose. The compensation elements 11 are respectively arranged in the depressions 7 and fill them at least partially. If the filler layer 9 and the cover 8 are now additionally provided, then the surface 10 will extend in an almost entirely planar fashion, and the conductor tracks 2 will no longer impinge on it. In the present embodiment, the cover 8 is formed by a one-piece cover element 12. The cover element 12 extends around the filler layer 9, with a first region and a second region 15 of the cover element 12 abutting together in the region of a connection position 13. Optionally, a gap 16 between the regions 14 and 15—if there is one—may be filled here with the filler layer 9. In the embodiment represented here, the connection position 13 lies on the upper side of the flexible circuit board 1.

FIG. 3 shows a region of the flexible circuit board 1 in a second embodiment. This differs from the one represented in FIG. 2 by the configuration of the cover element 12, or of the connection position 13. The cover element 12 may likewise be configured in one piece or a plurality of pieces in this embodiment. In the latter case, the connection position 13, which is in this case also formed like the connection position 13 represented here, is likewise present on the side of the circuit board 1 which is not represented here. If the cover element 12 is in one piece, however, then only the connection position 13 represented here exists. On the latter, the first region 14 and the second region 15 form a seam 17. The latter is filled with the filler layer 9, so that the regions 14 and 15 are held together adhesively. The cover 8 tapers in the region of the connection position 13, so that the regions 14 and 15 converge in order to form the seam 17.

FIG. 4 likewise shows a region of the circuit board 1, which is in a third embodiment. In this case, the regions 14 and 15 of the cover element 12 are arranged overlapping in the region of the connection position 13, so that there is an overlap 18.

FIG. 5 shows a region of a fourth embodiment of the circuit board 1. In this case, the regions 14 and 15 are separated from one another so that there is no connection position 13 as in the embodiments of FIGS. 2 to 4. Instead, the regions 14 and 15 extend essentially parallel to one another, while an end region 19 of the circuit board 1 is formed by the filler layer 9.

FIG. 6 shows a cross section of an electrical device 20. It comprises a housing 21 consisting of a first curved housing plate 22 and a second curved housing plate 23. An electrical module 24 is arranged and fastened in the housing 21. Through an opening 25 of the housing 21, the flexible circuit board 1 is led into the housing 21 of the electrical device 20. It can be seen here that the flexible circuit board 1 comprises the cover 8, and the filler layer 9, only in the region of the opening 25. It can furthermore be seen that the cover 8, the filler layer 9, the sheath 3 and the adhesive layer 4 are set back on the upper side of the circuit board 1 so that the conductor track 2 is at least partially exposed. On the exposed region of the conductor track 2 formed in this way, a bond connection 26 is provided which connects the conductor track 2 to the module 24, or to a terminal of the module 24. In this exemplary embodiment, the opening 25 is formed by a spacing between the curved housing plates 22 and 23. Between the curved housing plates 22 and 23 and the circuit board 1, sealing elements 27 are respectively arranged in order to protect the module 24 against external influences. The sealing elements 27 are provided in this case as separate components, which are fitted into recesses 28 of the curved housing plates 22 and 23. As an alternative, however, the sealing elements 27 may also be connected to the cover 8 or formed thereby. A further flexible circuit board 1 is provided on the right-hand side of the housing 21, although this is not represented in detail. Since it is configured in the same way as the circuit board 1 already described, it will not be discussed in any more detail here.

FIG. 7 shows the electrical device 20 in a view from above. It can be seen clearly that the module 24, which is arranged in the housing 21, is connected by means of a plurality of bond connections 26 to six circuit boards 1, which are respectively led out from the housing 21 through openings 25 thereof. It is also clear that the flexible circuit boards 1 respectively exist as an independent component and are not applied on a common carrier.

FIG. 8 shows a region of the device 20 in a view from above, only the first curved housing plate 22 of the housing 21 being represented. It is clear that the flexible circuit boards 1 are led into openings 25 of the curved housing plate 22, or of a filler element 29 which lies on the curved housing plate 22. The housing 21 shown in FIG. 8 is in a first manufacturing step of the electrical device 20.

FIG. 9 shows the electrical device 20 known from FIG. 8 in a second manufacturing step. In this case, a further filler element 29 is applied onto the first curved housing plate 22, and respectively the filler element 29 and the flexible circuit boards 1. These filler elements 29 ensure height equilibration between the circuit boards 1 and the surrounding regions, so that it is possible to seal the device 20 by fastening the second curved housing plate 23 on the first curved housing plate 22. As an alternative, the filler element may also be formed as a sealing strip. Thus, provision is made for such a sealing strip to be respectively arranged both below and above the circuit boards 1. Owing to the plane surface 10 of the cover 8, and respectively of the circuit board 1, very good leaktightness of the housing 21, or of the device 20, can be achieved in this way.

FIG. 10 shows a section of the device 20 known from FIG. 6. Firstly, the bond connection 26 by means of which the conductor track 2 is connected to the module (not shown here) can be seen. In the conventional way, the conductor track 2 is embedded by the adhesive layer 4, the sheath 3, the filler layer 9 and the cover 8. As already indicated in FIG. 6, the housing 21 is entirely filled with a filler compound 30. It is now provided in this case for the cover 8 to consist of a material which enters into a bond with this filler compound 30. There is thus intended to be a material-fit connection between the filler compound 30 and the cover 8, as is indicated in FIG. 10. In this way, a firm connection is achieved between the filler compound 30 and the cover 8. The flexible circuit board 1 is thus held in the housing 21. Such a device 20 may, for example, be produced by fastening the flexible circuit boards 1 and the module 24 on an intermediate carrier, for example by adhesive bonding, in order to achieve exact positioning. Then, the conductor tracks 2 of the circuit board 1 are connected to the module 24 by bonding, or establishing the bond connections 26. Optionally, the resulting module is tested. After a cleaning process, the filler compound 30 is injected around the module 24, for example in a mold. A thermosetting plastic may be used in this case as the filler compound 30, for example. In this case, provision is made for the filler compound 30 to form the housing 21 at least locally.

FIG. 11 shows an alternative embodiment of the electrical device 20. The housing 21 is represented, out from which a plurality of flexible circuit boards 1 are led. They may, for example, be provided in this case for the connection of a pressure regulator 31, a sensor 32, a jack connector 33 or the like. It is indicated in FIG. 11 that the flexible circuit boards 1 comprise the cover 8 only in the region in which they are led out from the housing 21. The rest of the circuit board 1 constitutes a flexible circuit board 1 as is known from the prior art (i.e. without a filler layer 9 and a cover 8), in order not to compromise the flexibility.

1. A flexible circuit board comprising:
at least one conductor track;
at least one sheath at least locally enclosing the conductor track;
at least one adhesive layer configured to fasten the sheath to the conductor track, the at least one adhesive layer positioned between the conductor track and the sheath;
a cover which at least locally lies over the sheath; and
at least one filler layer positioned between the sheath and the cover.

2. The flexible circuit board of claim 1, that wherein the at least one filler layer establishes an adhesive bond between the sheath and the cover.

3. The flexible circuit board of claim 1, further comprising at least one compensation element comprising a plastic and/or metal or consisting of plastic and/or metal, the at least one compensation element arranged in the filler layer.

4. The flexible circuit board of claim 1, further comprising a sealing element, in particular a lip seal, positioned on the cover.

5. The flexible circuit board of claim 1, wherein the cover is formed by a circumferential sleeve and/or a one-piece or multi-piece cover element.

6. The flexible circuit board of claim 5, wherein the one-piece or multi-piece cover element includes at least one connection position in which a first region of the cover element abuts or forms a seam or an overlap with a second region of the cover element.

7. An electrical device, in particular a control unit for a vehicle, comprising:
a housing having an opening; and
at least one flexible circuit board, including:
at least one conductor track led out from the housing through the opening;
at least one sheath at least locally enclosing the conductor track;
at least one adhesive layer configured to fasten the sheath to the conductor track, the at least one adhesive layer positioned between the conductor track and the sheath;
a cover which at least locally lies over the sheath; and
at least one filler layer positioned between the sheath and the cover.

8. The electrical device of claim 7, wherein the housing is at least locally filled with a filler compound.

9. The electrical device of claim 7, wherein the cover is provided at least in the region of the opening.

10. The electrical device of claim 8, wherein the cover consists of a material, in particular plastic and/or metal, which enters into a bond with the filler compound.
